(19) United States
(12) Patent Application Publication
(10) Pub. No.: US 2025/0255112 A1
(43) Pub. Date: Aug. 7, 2025

(54) DISPLAY PANEL AND DISPLAY TERMINAL

(71) Applicant: Shenzhen China Star Optoelectronics Semiconductor Display Technology Co., Ltd., Shenzhen (CN)

(72) Inventor: Wei YUAN, Shenzhen (CN)

(73) Assignee: Shenzhen China Star Optoelectronics Semiconductor Display Technology Co., Ltd., Shenzhen (CN)

(21) Appl. No.: 19/037,212

(22) Filed: Jan. 26, 2025

(30) Foreign Application Priority Data
Feb. 1, 2024 (CN) 202410157671.2

(51) Int. Cl. H10K 59/122; H10K 59/35; H10K 59/80

(52) U.S. Cl. CPC H10K 59/122; H10K 59/80521; H10K 59/35

(57) ABSTRACT

A display panel and a display terminal are provided, featuring an anode layer, a pixel definition layer, an isolation structure with an auxiliary cathode and an isolation layer forming a groove, a light-emitting functional layer, and a cathode layer with cathodes designed to cover the light-emitting functional layer and extend into the grooves to contact the auxiliary cathodes. The pixel definition layer includes a first barrier wall and a second barrier wall. As the thickness of the first color sub-layer is greater than that of the second color sub-layer, the thickness of the first barrier wall is set to be greater than that of the second barrier wall. This ensures that the cathodes contact the corresponding auxiliary cathodes accurately, achieving normal contact between the cathode and the auxiliary cathode, and significantly improving electrical connection reliability despite variations in the thickness of the light-emitting function layer.

### FIELD OF DISCLOSURE

The present application relates to a field of display technology, particularly relating to a display panel and a display terminal.

### DESCRIPTION OF RELATED ART

Organic light-emitting diode (OLED) display technology is a new type of display technology that has gradually gained attention due to its unique advantages such as low power consumption, high saturation, fast response times, and wide viewing angles, holding a significant position in the field of panel display technology.

An OLED light-emitting unit consists of sequentially stacked layers: an anode, a light-emitting functional layer, and a cathode. A cathode layer is thin and has high impedance. To reduce the impedance of the cathode, auxiliary cathodes are often added and connected in parallel with the cathode. Due to the varying thicknesses of the light-emitting functional layers for different colored sub-pixels, while the thickness of a pixel definition layer remains constant, excessively thick or thin light-emitting functional layers can cause abnormal overlap between the cathode and the auxiliary cathode.

Thus, there is an urgent need to address the above technical issues.

### SUMMARY OF INVENTION

The present application provides a display panel and a display terminal to address technical issues arising from abnormal overlaps between cathodes and auxiliary cathodes when the thicknesses of light-emitting functional layers of sub-pixels of different colors vary.

To solve the aforementioned technical issues, the technical solutions provided in this application are as follows:

The present application provides a display panel, including:
a substrate;
an anode layer located on one side of the substrate, wherein the anode layer includes a plurality of anodes;
a pixel definition layer disposed on one side of the anode layer facing away from the substrate, the pixel definition layer including a plurality of openings, wherein each of the openings is defined corresponding to one of the anodes;
a plurality of isolation structures disposed on one side of the pixel definition layer facing away from the substrate, wherein an orthographic projection of the isolation structure on the pixel definition layer is within the pixel definition layer, the isolation structure including an auxiliary cathode and an isolation layer, with the isolation layer disposed on one side of the auxiliary cathode facing away from the substrate, and a side wall of the auxiliary cathode indented relative to a side wall of the isolation layer to form a groove;
a light-emitting functional layer disposed in the openings and covering the anodes, the light-emitting functional layer including a first color sub-layer and a second color sub-layer disposed in respective ones of the openings, wherein a thickness of the first color sub-layer is greater than a thickness of the second color sub-layer; and
a cathode layer covering the light-emitting functional layer, the cathode layer including a plurality of cathodes, wherein the cathode extends into the groove and makes contact with the auxiliary cathode;
wherein the pixel definition layer includes a first barrier wall and a second barrier wall extending along a first direction, two ends of the first color sub-layer are respectively connected to the first barrier wall and the second barrier wall, the second color sub-layer near one end of the first color sub-layer is connected to the second barrier wall, and a thickness of the first barrier wall is greater than a thickness of the second barrier wall.

In the display panel of the present application, the cathodes include a first sub-part and a second sub-part, the first sub-part covering the first color sub-layer, the second sub-part covering the second color sub-layer; wherein the first sub-part is at least electrically connected to the auxiliary cathode corresponding to the first barrier wall; the second sub-part is at least electrically connected to the auxiliary cathode corresponding to the second barrier wall.

In the display panel of the present application, a contact area of the first sub-part with the auxiliary cathode corresponding to the first barrier wall is greater than a contact area of the first sub-part with the auxiliary cathode corresponding to the second barrier wall; and/or, a thickness of the first sub-part near an end close to the first barrier wall is greater than a thickness of the first sub-part near an end close to the second barrier wall.

In the display panel of the present application, the thickness of the first barrier wall is greater than or equal to the thickness of the first color sub-layer, a distance between a surface of the first barrier wall away from the substrate and a surface of the first color sub-layer away from the substrate is a first distance, the first distance being less than or equal to an average thickness of the first sub-part; a distance between a surface of the second barrier wall away from the substrate and a surface of the anode away from the substrate is a second distance, the second distance being less than or equal to an average thickness of the second sub-part.

In the display panel of the present application, a maximum thickness of the first sub-part and a maximum thickness of the second sub-part are both less than a thickness of the auxiliary cathode, and each auxiliary cathode is equal in thickness.

In the display panel of the present application, a metal wiring layer is disposed between the substrate and the pixel definition layer, and the auxiliary cathode is electrically connected to the metal wiring layer through a via hole.

In the display panel of the present application, the first color sub-layer is a green light-emitting layer, and the second color sub-layer is a blue light-emitting layer.

In the display panel of the present application, the display panel further includes an auxiliary encapsulation layer, the auxiliary encapsulation layer includes a plurality of auxiliary encapsulation parts spaced apart, and the auxiliary encapsulation parts cover the cathodes and inner walls of the grooves corresponding to the cathodes.

In the display panel of the present application, the light-emitting functional layer includes a third color sub-layer, the first color sub-layer, the second color sub-layer, and the third color sub-layer are disposed in different openings, a thickness of the third color sub-layer is greater than the thickness of the first color sub-layer, the pixel definition layer includes a third barrier wall extending along the first direction, one end of the third color sub-layer is connected to the first barrier wall and the other end of the third color sub-layer is connected to the third barrier wall, and a thickness of the third barrier wall is greater than or equal to the thickness of the first barrier wall.

The present application further provides a display terminal, including the display panel mentioned above.

Advantages: The present application provides a display panel and a display terminal. The application provides a display panel which includes a substrate, an anode layer, a pixel definition layer, a plurality of isolation structures, a light-emitting functional layer, and a cathode layer. The anode layer is positioned on one side of the substrate and includes a plurality of anodes; the pixel definition layer is set on one side of the anode layer away from the substrate and has a plurality of openings, each opening corresponding to an anode; the isolation structure is positioned on one side of the pixel definition layer away from the substrate, and an orthographic projection of the isolation structure on the pixel definition layer is within the pixel definition layer, including an auxiliary cathode and an isolation layer, with the isolation layer positioned on one side of the auxiliary cathode away from the substrate, and a side wall of the auxiliary cathode is indented relative to a side wall of the isolation layer to form a groove; the light-emitting functional layer is disposed within the openings and covers the anodes, including a first color sub-layer and a second color sub-layer set in different openings, with a thickness of the first color sub-layer greater than a thickness of the second color sub-layer; the cathode layer covers the light-emitting functional layer and includes a plurality of cathodes, the cathode extending into the groove and contacting the auxiliary cathode; the pixel definition layer includes a first barrier wall and a second barrier wall extending in a first direction, with two ends of the first color sub-layer respectively connected to the first and second barrier walls, and an end of the second color sub-layer near the first color sub-layer connected to the second barrier wall, with a thickness of the first barrier wall greater than a thickness of the second barrier wall. As the thickness of the first color sub-layer is greater than the thickness of the second color sub-layer, the thickness of the first barrier wall adjacent to the first color sub-layer is made greater than the thickness of the second barrier wall adjacent to the second color sub-layer, enabling the cathode corresponding to the first color sub-layer to contact the auxiliary cathode on the first barrier wall, and the cathode corresponding to the second color sub-layer to contact the auxiliary cathode on the second barrier wall, thereby achieving normal contact between the cathode and the auxiliary cathode and addressing the issue of abnormal electrical connections caused by the differing thicknesses of the first and second color sub-layers.

### BRIEF DESCRIPTION OF DRAWINGS

The following description, in conjunction with the accompanying drawings, provides a detailed explanation of specific embodiments of the present application, making the technical solutions and other beneficial effects of the present application readily apparent.

FIG. 1 provides a schematic top view of a display panel according to one embodiment of the present application.

FIG. 2 is a schematic cross-sectional view taken along line C-C in FIG. 1.

FIG. 3 is a schematic enlarged view of a local structure at location D in FIG. 2.

### DESCRIPTION OF REFERENCE NUMERALS IN THE DRAWING

substrate 10, thin film transistor 90, display area AA, non-display area NA, pixel definition layer 20, opening 24, first barrier wall 21, second barrier wall 22, third barrier wall 23, thickness d1 of the first barrier wall 21, thickness d2 of the second barrier wall 22, thickness d3 of the third barrier wall 23, light-emitting functional layer 30, first color sub-layer 31, second color sub-layer 32, third color sub-layer 33, isolation structure 40, auxiliary cathode 41, isolation layer 42, cathode layer 50, cathode 51, first sub-part 511, second sub-part 512, third sub-part 513, anode layer 60, anode 61, metal wiring layer 70, auxiliary encapsulation layer 80, auxiliary encapsulation part 81, first distance s1, second distance s2, third distance s3, first direction D1, second direction D2.

### DETAILED DESCRIPTION OF EMBODIMENTS

In the following, a clear and complete description of the technical solutions in the embodiments of the present application is provided in conjunction with the accompanying drawings. Clearly, the embodiments described here are just part of the embodiments of this application, not all of them. Based on the embodiments in this application, all other embodiments obtained by those skilled in the art without creative effort fall within the scope of protection of this application. Furthermore, it should be understood that the specific implementations described here are used only to illustrate and explain this application and are not intended to limit the application. In this application, unless otherwise stated, directional terms such as “above” and “below” typically refer to the up and down in the actual use or operational state of the device, specifically as shown in the direction in the drawings; “inner” and “outer” refer to the contours of the device.

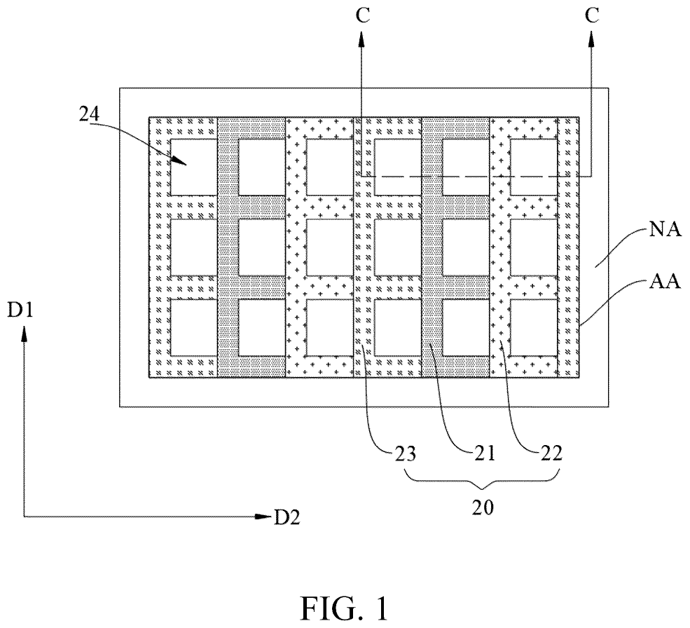

The present application provides a display panel as shown in FIGS. 1 to 3, which includes a substrate 10, an anode layer 60, a pixel definition layer 20, an isolation structure 40, a light-emitting functional layer 30, and a cathode layer 50. The anode layer 60 is disposed on one side of substrate 10 and includes a plurality of anodes 61; the pixel definition layer 20 is positioned on one side of anode layer 60 away from substrate 10 and includes a plurality of openings 24, each opening 24 corresponding to one anode 61. The isolation structure 40 is positioned on one side of the pixel definition layer 20 away from substrate 10, and an orthographic projection of the isolation structure 40 on the pixel definition layer 20 is within the pixel definition layer 20. The isolation structure 40 includes an auxiliary cathode 41 and an isolation layer 42, with the isolation layer 42 positioned on one side of the auxiliary cathode 41 away from substrate 10. A side wall of the auxiliary cathode 41 is indented relative to a side wall of the isolation layer 42 to form a groove. The light-emitting functional layer 30 is disposed within the openings 24 and covers the anodes 61, including a first color sub-layer 31 and a second color sub-layer 32 set in different openings 24, with a thickness of the first color sub-layer 31 greater than a thickness of the second color sub-layer 32. The cathode layer 50 covers the light-emitting functional layer 30 and includes a plurality of cathodes 51. The cathode 51 extends into the groove and contacts the auxiliary cathode 41. The pixel definition layer 20 includes a first barrier wall 21 and a second barrier wall 22 extending along a first direction D1. Two ends of the first color sub-layer 31 are respectively connected to the first barrier wall 21 and the second barrier wall 22, and one end of the second color sub-layer 32 near the first color sub-layer 31 is connected to the second barrier wall 22, with a thickness d1 of the first barrier wall 21 greater than a thickness d2 of the second barrier wall 22.

In the present embodiment, the display panel can be an OLED panel, Mini-LED panel, or Micro-LED panel.

In this embodiment, the substrate 10 can be a flexible substrate or a rigid substrate. Materials for the flexible substrate may include polyimide, polycarbonate, polyethersulfone, polyethylene terephthalate, polyethylene naphthalate, polyarylate, or glass fiber reinforced plastic. The material for the rigid substrate can be glass, among others.

In the present embodiment, the substrate 10 also has a driving circuit thereon, which includes a plurality of thin-film transistors (TFT) 90 used to drive light-emitting units to emit light.

In the present embodiment, the pixel definition layer 20 is set upon the substrate 10 and includes multiple openings 24, with the light-emitting functional layer 30 set within the openings 24. The display panel includes a display area AA and a non-display area NA set around the display area AA. The display area AA includes multiple sub-pixels, each sub-pixel corresponding to one opening 24. Inside the opening 24, there are sequentially stacked the anode 61, the light-emitting functional layer 30, and the cathode 51, with the anode 61 injecting holes and the cathode 51 injecting electrons, and the holes and the electrons combine in the light-emitting functional layer 30 to produce light.

In the present embodiment, the light-emitting functional layer 30 can include stacked layers such as a hole injection layer, a hole transport layer, an emissive layer, an electron transport layer, and an electron injection layer.

The pixel definition layer 20 includes the first barrier wall 21 and the second barrier wall 22 extending in the first direction D1. It should be noted that the extension of the first barrier wall 21 in the first direction D1 refers to the overall extension trend of the first barrier wall 21 in the first direction D1 and does not imply that a boundary line of the first barrier wall 21 must be straight. For example, when the opening 24 is rectangular, the first barrier wall 21 extends in the first direction D1, and when the opening 24 is circular or of another shape, the first barrier wall 21 still extends in the first direction D1. The setting of the second barrier wall 22 is similar.

The first color sub-layer 31 and the second color sub-layer 32 are disposed in different openings 24 and can be arranged along the second direction D2.

The first direction D1 and the second direction D2 are different, and the first direction D1 and the second direction D2 can be set at an angle to each other, which can be an acute angle, a right angle, or an obtuse angle.

Along the second direction D2, one end of the second barrier wall 22 is connected to the first color sub-layer 31, and the other end of the second barrier wall 22 is connected to the second color sub-layer 32. The first barrier wall 21 is positioned at one end of the first color sub-layer 31 that is away from the second barrier wall 22, and the first barrier wall 21 is connected to the first color sub-layer 31.

It should be noted that “connected” refers to contact in the direction parallel to the plane of substrate 10.

In the present embodiment, an orthographic projection of the isolation structure 40 on the pixel definition layer 20 is within the pixel definition layer 20, meaning that the orthographic projection of the isolation structure 40 does not exceed the pixel definition layer 20.

In the direction parallel to substrate 10, an edge of the isolation layer 42 extends beyond an edge of the auxiliary cathode 41, and a profile of the auxiliary cathode 41 in the direction parallel to substrate 10 is indented relative to a profile of the isolation layer 42 in the same direction, forming a recess, i.e., the isolation layer 42 and the auxiliary cathode 41 form a bottom-cut structure.

A material of the isolation layer 42 can be an inorganic material. For example, the isolation layer 42 can be a stack of silicon nitride and silicon dioxide.

By implementing the isolation structure 40, the light-emitting functional layer 30 can be segmented, which allows for the patterning of the light-emitting functional layer 30 using photolithography techniques without the need for a fine metal mask (FMM). This approach not only facilitates the free design of the pattern shapes of the light-emitting functional layer 30 but also eliminates the need for the expensive FMM, significantly reducing the manufacturing costs of the display panel.

In the present embodiment, the thickness refers to a dimension perpendicular to the plane of the substrate 10. The thickness d1 of the first barrier wall 21 is greater than the thickness d2 of the second barrier wall 22. The thickness d1 of the first barrier wall 21 can range from 0.25 micrometers to 0.33 micrometers, for example, the thickness d1 can be 0.26 micrometers, 0.27 micrometers, 0.28 micrometers, 0.29 micrometers, 0.30 micrometers, 0.31 micrometers, 0.32 micrometers, or 0.33 micrometers. The thickness d2 of the second barrier wall 22 can range from 0.15 micrometers to 0.23 micrometers. For example, the thickness d2 can be 0.15 micrometers, 0.16 micrometers, 0.17 micrometers, 0.18 micrometers, 0.19 micrometers, 0.20 micrometers, 0.21 micrometers, 0.22 micrometers, or 0.23 micrometers.

The pixel definition layer 20 can be manufactured using a half-tone mask or a gray tone mask, thus not increasing the number of photomasks needed and saving on production costs.

In the display panel of the present application, the display panel can include an auxiliary encapsulation layer 80, which includes multiple spaced auxiliary encapsulation parts 81. The auxiliary encapsulation parts 81 cover the cathodes 51 and the inner walls of the grooves corresponding to the cathodes 51.

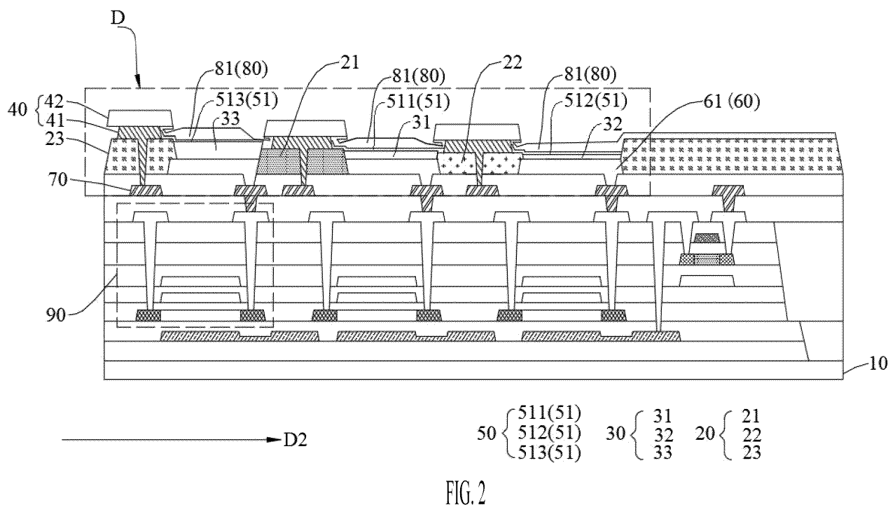

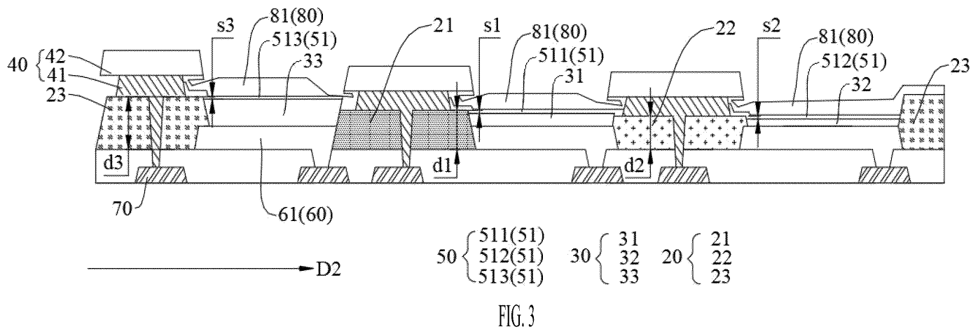

In the display panel of the present application, as shown in FIGS. 2 and 3, the cathodes 51 include a first sub-part 511 and a second sub-part 512. The first sub-part 511 covers the first color sub-layer 31, and the second sub-part 512 covers the second color sub-layer 32. The first sub-part 511 is at least electrically connected to the auxiliary cathode 41 corresponding to the first barrier wall 21; the second sub-part 512 is at least electrically connected to the auxiliary cathode 41 corresponding to the second barrier wall 22.

In this embodiment, the cathode 51 can be manufactured using a vapor deposition process. By adjusting the angle of the deposition through the photomask, the first sub-part 511 can be exclusively connected electrically to the auxiliary cathode 41 corresponding to the first barrier wall 21. Specifically, when the angle of the vapor deposition photomask is tilted towards the side of the first barrier wall 21, more metal material is deposited on the side closer to the first barrier wall 21, thereby ensuring that the first sub-part 511 is electrically connected to the auxiliary cathode 41 corresponding to the first barrier wall 21. Similarly, more metal material is deposited on the side closer to the second barrier wall 22, allowing the second sub-part 512 to connect electrically with the auxiliary cathode 41 corresponding to the second barrier wall 22.

Through the above setup, a contact area between the cathode 51 and the auxiliary cathode 41 can be increased, thereby enhancing the reliability of the connection between the cathode 51 and the auxiliary cathode 41.

In the display panel of the present application, the contact area of the first sub-part 511 with the auxiliary cathode 41 corresponding to the first barrier wall 21 is greater than the contact area of the first sub-part 511 with the auxiliary cathode 41 corresponding to the second barrier wall 22; and/or the thickness of the first sub-part 511 near an end close to the first barrier wall 21 is greater than the thickness of the first sub-part 511 near an end close to the second barrier wall 22.

In the present embodiment, a portion of the first sub-part 511 is deposited within the groove corresponding to the first barrier wall 21, and the contact area of the first sub-part 511 with the auxiliary cathode 41 corresponding to the first barrier wall 21 is greater than the contact area of the first sub-part 51 with the auxiliary cathode 41 corresponding to the second barrier wall 22.

A portion of the second sub-part 512 is deposited within the groove corresponding to the second barrier wall 22, and the contact area of the second sub-part 512 with the auxiliary cathode 41 corresponding to the second barrier wall 22 is greater than the contact area of the second sub-part 512 with the auxiliary cathode 41 corresponding to an opposite-side barrier wall.

In the display panel of this application, as shown in FIGS. 2 and 3, the thickness d1 of the first barrier wall 21 is greater than or equal to the thickness of the first color sub-layer 31. A distance between a surface of the first barrier wall 21 away from the substrate 10 and a surface of the first color sub-layer 31 away from the substrate 10 is referred to as a first distance s1. The first distance s1 is less than or equal to the average thickness of the first sub-part 511. A distance between a surface of the second barrier wall 22 away from the substrate 10 and a surface of the anode 61 away from the substrate 10 is referred to as a second distance s2. The second distance s2 is less than or equal to the average thickness of the second sub-part 512.

In the present embodiment, the thickness d1 of the first barrier wall 21 is greater than or equal to the thickness of the first color sub-layer 31, thereby ensuring that the first color sub-layer 31 does not extend beyond the pixel definition layer 20 and preventing any leakage currents that may arise from a connection between the first color sub-layer 31 and the auxiliary cathode 41.

The thickness of the first color sub-layer 31 can range from 0.2 micrometers to 0.23 micrometers. For example, the thickness of the first color sub-layer 31 may be 0.2 micrometers, 0.21 micrometers, 0.22 micrometers, or 0.23 micrometers.

In the present embodiment, the thickness d2 of the second barrier wall 22 is greater than or equal to the thickness of the second color sub-layer 32, thereby ensuring that the second color sub-layer 32 does not extend beyond the pixel definition layer 20 and avoiding any leakage currents that may result from a connection between the second color sub-layer 32 and the auxiliary cathode 41.

The thickness of the second color sub-layer 32 can range from 0.14 micrometers to 0.17 micrometers. For example, the thickness of the second color sub-layer 32 may be 0.14 micrometers, 0.15 micrometers, 0.16 micrometers, or 0.17 micrometers.

It should be understood that due to limitations in manufacturing precision, the thickness of the pixel definition layer 20 or the light-emitting functional layer 30 may exhibit deviations. For instance, the tolerance (the range of deviation) might be ±0.02 micrometers. Therefore, if the thickness of the first color sub-layer 31 is within 0.02 micrometers greater than the thickness d1 of the first barrier wall 21, it should still be considered that the thickness d1 of the first barrier wall 21 is greater than or equal to the thickness of the first color sub-layer 31. Similarly, if the thickness of the second color sub-layer 32 is within 0.02 micrometers greater than the thickness d2 of the second barrier wall 22, it should still be considered that the thickness d2 of the second barrier wall 22 is greater than or equal to the thickness of the second color sub-layer 32.

In the display panel of the present application, the maximum thickness of the first sub-part 511 and the maximum thickness of the second sub-part 512 are both less than the thickness of the auxiliary cathode 41, and the thickness of each auxiliary cathode 41 is uniform. This configuration prevents the first sub-part 511 and the second sub-part 512 from completely filling the grooves, thereby allowing the grooves to facilitate the discontinuation of the auxiliary encapsulation layer 80.

In the present embodiment, the maximum thickness of the first sub-part 511 is the thickness near the groove where the first sub-part 511 electrically connects with the auxiliary cathode 41. Similarly, the maximum thickness of the second sub-part 512 is the thickness near the groove where the second sub-part 512 makes an electrical connection with the auxiliary cathode 41.

In the present embodiment, assuming uniform manufacturing precision, the thickness of the auxiliary cathode 41 is consistent, with all auxiliary cathodes 41 having the same thickness.

In the display panel of the present application, as shown in FIGS. 2 and 3, a metal wiring layer 70 is disposed between the substrate 10 and the pixel definition layer 20, and the auxiliary cathode 41 is electrically connected to the metal wiring layer 70 through via holes. Since the cathodes 51 corresponding to the openings 24 are separately set, to facilitate the input of voltage signals to each cathode 51, the auxiliary cathode 41 can be electrically connected to the metal wiring layer 70. The metal wiring layer 70 can also be electrically connected to a signal input terminal, thereby enabling the input of voltage signals to the cathode 51 through the metal wiring layer 70.

In the display panel of the present application, the first color sub-layer 31 is a green light-emitting layer, and the second color sub-layer 32 is a blue light-emitting layer.

In the display panel of this application, as shown in FIGS. 2 and 3, the light-emitting functional layer 30 includes a third color sub-layer 33. The first color sub-layer 31, the second color sub-layer 32, and the third color sub-layer 33 are disposed in different openings 24. A thickness of the third color sub-layer 33 is greater than the thickness of the first color sub-layer 31. The pixel definition layer 20 includes a third barrier wall 23 extending along the first direction D1, with one end of the third color sub-layer 33 connected to the first barrier wall 21 and the other end of the third color sub-layer 33 connected to the third barrier wall 23. A thickness d3 of the third barrier wall 23 is greater than or equal to the thickness d1 of the first barrier wall 21.

In the present embodiment, the third color sub-layer 33 can be a red light-emitting layer, with the thickness of the third color sub-layer 33 ranging from 0.27 micrometers to 0.3 micrometers. For example, the thickness of the third color sub-layer 33 can be 0.27 micrometers, 0.28 micrometers, 0.29 micrometers, or 0.3 micrometers.

The cathodes 51 include a third sub-part 513. The third sub-part 513 covers the third color sub-layer 33, and the third sub-part 513 is at least electrically connected to the auxiliary cathode 41 corresponding to the third barrier wall 23.

In the present embodiment, the third barrier wall 23 is positioned on one side of the third color sub-layer 33 that is far from the first barrier wall 21. This means that one end of the third color sub-layer 33 is connected to the third barrier wall 23, and the other end of the third color sub-layer is connected to the first barrier wall 21.

In the present embodiment, the thickness d3 of the third barrier wall 23 is greater than or equal to the thickness d1 of the first barrier wall 21. The thickness d3 of the third barrier wall 23 can range from 0.3 micrometers to 0.4 micrometers. The distance between a surface of the third barrier wall 23 away from the substrate 10 and a surface of the third color sub-layer 33 away from the substrate 10 is referred to as the third distance s3, and the third distance s3 is less than or equal to the average thickness of the third sub-part 513. The thickness d3 of the third barrier wall 23 can be greater than or equal to the thickness of the third color sub-layer 33.

In the present embodiment, a contact area of the third sub-part 513 with the auxiliary cathode 41 corresponding to the third barrier wall 23 is greater than a contact area of the third sub-part with the auxiliary cathode 41 corresponding to the first barrier wall 21; and/or, the thickness of the third sub-part 513 near the end close to the third barrier wall 23 is greater than the thickness of the third sub-part 513 near the end close to the first barrier wall 21.

The present application also provides a display terminal. The display terminal includes the display panel described above.

In the present embodiment, the display terminal can be any product or component with a display function, such as a mobile phone, tablet computer, television, monitor, laptop, digital photo frame, navigation device, etc.

In the described embodiments, the description of each embodiment varies in focus, and details not elaborated in a particular embodiment can be found in the descriptions of other embodiments.

The above descriptions have provided a detailed introduction to the display panel and the display terminal offered in the embodiments of the present application. This disclosure has used specific examples to elucidate the principles and implementations of the application. The explanations of these embodiments are intended solely to aid in understanding the technical solutions and core ideas of this application; it should be understood by those of ordinary skill in the field that they may still modify the technical solutions described in the aforementioned embodiments, or equivalently substitute some of their technical features; and these modifications or substitutions do not depart from the essence of the technical solutions of the embodiments of this application.

What is claimed is:

1. A display panel, comprising:
a substrate;
an anode layer located on one side of the substrate, wherein the anode layer comprises a plurality of anodes;
a pixel definition layer disposed on one side of the anode layer facing away from the substrate, the pixel definition layer comprising a plurality of openings, wherein each of the openings is defined corresponding to one of the anodes;
a plurality of isolation structures disposed on one side of the pixel definition layer facing away from the substrate, wherein an orthographic projection of the isolation structure on the pixel definition layer is within the pixel definition layer, the isolation structure comprising an auxiliary cathode and an isolation layer, with the isolation layer disposed on one side of the auxiliary cathode facing away from the substrate, and a side wall of the auxiliary cathode indented relative to a side wall of the isolation layer to form a groove;
a light-emitting functional layer disposed in the openings and covering the anodes, the light-emitting functional layer comprising a first color sub-layer and a second color sub-layer disposed in respective ones of the openings, wherein a thickness of the first color sub-layer is greater than a thickness of the second color sub-layer; and
a cathode layer covering the light-emitting functional layer, the cathode layer comprising a plurality of cathodes, wherein the cathode extends into the groove and makes contact with the auxiliary cathode;
wherein the pixel definition layer comprises a first barrier wall and a second barrier wall extending along a first direction, two ends of the first color sub-layer are respectively connected to the first barrier wall and the second barrier wall, the second color sub-layer near one end of the first color sub-layer is connected to the second barrier wall, and a thickness of the first barrier wall is greater than a thickness of the second barrier wall.

2. The display panel according to claim 1, wherein the cathodes comprise a first sub-part and a second sub-part, the first sub-part covering the first color sub-layer, the second sub-part covering the second color sub-layer; wherein the first sub-part is at least electrically connected to the auxiliary cathode corresponding to the first barrier wall; the second sub-part is at least electrically connected to the auxiliary cathode corresponding to the second barrier wall.

3. The display panel according to claim 2, wherein a contact area of the first sub-part with the auxiliary cathode corresponding to the first barrier wall is greater than a contact area of the first sub-part with the auxiliary cathode corresponding to the second barrier wall; and/or, a thickness of the first sub-part near an end close to the first barrier wall is greater than a thickness of the first sub-part near an end close to the second barrier wall.

4. The display panel according to claim 2, wherein the thickness of the first barrier wall is greater than or equal to the thickness of the first color sub-layer, a distance between a surface of the first barrier wall away from the substrate and a surface of the first color sub-layer away from the substrate is a first distance, the first distance being less than or equal to an average thickness of the first sub-part; a distance between a surface of the second barrier wall away from the substrate and a surface of the anode away from the substrate is a second distance, the second distance being less than or equal to an average thickness of the second sub-part.

5. The display panel according to claim 2, wherein a maximum thickness of the first sub-part and a maximum thickness of the second sub-part are both less than a thickness of the auxiliary cathode, and each auxiliary cathode is equal in thickness.

6. The display panel according to claim 1, wherein a metal wiring layer is disposed between the substrate and the pixel definition layer, and the auxiliary cathode is electrically connected to the metal wiring layer through a via hole.

7. The display panel according to claim 1, wherein the first color sub-layer is a green light-emitting layer, and the second color sub-layer is a blue light-emitting layer.

8. The display panel according to claim 1, further comprising an auxiliary encapsulation layer, the auxiliary encapsulation layer comprising a plurality of auxiliary encapsulation parts spaced apart, the auxiliary encapsulation parts covering the cathodes and inner walls of the grooves corresponding to the cathodes.

9. The display panel according to claim 1, wherein the light-emitting functional layer comprises a third color sub-layer, the first color sub-layer, the second color sub-layer, and the third color sub-layer are disposed in different openings, a thickness of the third color sub-layer is greater than the thickness of the first color sub-layer, the pixel definition layer comprises a third barrier wall extending along the first direction, one end of the third color sub-layer is connected to the first barrier wall and the other end of the third color sub-layer is connected to the third barrier wall, and a thickness of the third barrier wall is greater than or equal to the thickness of the first barrier wall.

10. A display terminal, comprising a display panel, wherein the display panel comprises:
a substrate;
an anode layer located on one side of the substrate, wherein the anode layer comprises a plurality of anodes;
a pixel definition layer disposed on one side of the anode layer facing away from the substrate, the pixel definition layer comprising a plurality of openings, each opening is defined corresponding to one of the anodes;
a plurality of isolation structures disposed on one side of the pixel definition layer facing away from the substrate, wherein an orthographic projection of the isolation structure on the pixel definition layer is within the pixel definition layer, the isolation structure comprising an auxiliary cathode and an isolation layer, with the isolation layer disposed on one side of the auxiliary cathode facing away from the substrate, and a side wall of the auxiliary cathode indented relative to a side wall of the isolation layer to form a groove;
a light-emitting functional layer disposed within the openings and covering the anodes, the light-emitting functional layer comprising a first color sub-layer and a second color sub-layer disposed in respective ones of the openings, wherein a thickness of the first color sub-layer is greater than a thickness of the second color sub-layer; and
a cathode layer covering the light-emitting functional layer, the cathode layer comprising a plurality of cathodes, wherein the cathode extends into the groove and makes contact with the auxiliary cathode;
wherein the pixel definition layer comprises a first barrier wall and a second barrier wall extending along a first direction, two ends of the first color sub-layer are respectively connected to the first and second barrier walls, and the second color sub-layer near one end of the first color sub-layer is connected to the second barrier wall, and a thickness of the first barrier wall is greater than a thickness of the second barrier wall.

11. The display terminal according to claim 10, wherein the cathodes comprise a first sub-part and a second sub-part, the first sub-part covering the first color sub-layer, the second sub-part covering the second color sub-layer; wherein the first sub-part is at least electrically connected to the auxiliary cathode corresponding to the first barrier wall; the second sub-part is at least electrically connected to the auxiliary cathode corresponding to the second barrier wall.

12. The display terminal according to claim 11, wherein a contact area of the first sub-part with the auxiliary cathode corresponding to the first barrier wall is greater than a contact area of the first sub-part with the auxiliary cathode corresponding to the second barrier wall; and/or, a thickness of the first sub-part near an end close to the first barrier wall is greater than a thickness of the first sub-part near an end close to the second barrier wall.

13. The display terminal according to claim 11, wherein the thickness of the first barrier wall is greater than or equal to the thickness of the first color sub-layer, a distance between a surface of the first barrier wall away from the substrate and a surface of the first color sub-layer away from the substrate is a first distance, the first distance being less than or equal to an average thickness of the first sub-part; a distance between a surface of the second barrier wall away from the substrate and a surface of the anode away from the substrate is a second distance, the second distance being less than or equal to an average thickness of the second sub-part.

14. The display terminal according to claim 11, wherein a maximum thickness of the first sub-part and a maximum thickness of the second sub-part are both less than a thickness of the auxiliary cathode, and each auxiliary cathode is equal in thickness.

15. The display terminal according to claim 10, wherein a metal wiring layer is disposed between the substrate and the pixel definition layer, and the auxiliary cathode is electrically connected to the metal wiring layer through a via hole.

16. The display terminal according to claim 10, wherein the first color sub-layer is a green light-emitting layer, and the second color sub-layer is a blue light-emitting layer.

17. The display terminal according to claim 10, further comprising an auxiliary encapsulation layer, the auxiliary encapsulation layer comprising a plurality of auxiliary encapsulation parts spaced apart, the auxiliary encapsulation parts covering the cathodes and inner walls of the grooves corresponding to the cathodes.

18. The display terminal according to claim 10, wherein the light-emitting functional layer comprises a third color sub-layer, the first color sub-layer, the second color sub-layer, and the third color sub-layer are disposed in different openings, a thickness of the third color sub-layer is greater than the thickness of the first color sub-layer, the pixel definition layer comprises a third barrier wall extending along the first direction, one end of the third color sub-layer is connected to the first barrier wall and the other end of the third color sub-layer is connected to the third barrier wall, and a thickness of the third barrier wall is greater than or equal to the thickness of the first barrier wall.
